(19) United States
(12) Patent Application Publication
(10) Pub. No.: US 2025/0291501 A1
(43) Pub. Date: Sep. 18, 2025

(54) SEMICONDUCTOR MEMORY DEVICE

(71) Applicant: Kioxia Corporation, Tokyo (JP)

(72) Inventors: Hiroyuki ISHII, Kamakura Kanagawa (JP); Katsuki MATSUDERA, Kamakura Kanagawa (JP)

(21) Appl. No.: 19/072,633

(22) Filed: Mar. 6, 2025

(30) Foreign Application Priority Data
Mar. 15, 2024 (JP) 2024-041212

(51) Int. Cl. G06F 3/06; G11C 16/04; G11C 16/10; G11C 16/26; H10B 43/27; H10B 43/35

(52) U.S. Cl. CPC G06F 3/0626; G06F 3/0629; G06F 3/0679; G11C 16/10; G11C 16/26; G11C 16/0483; H10B 43/27; H10B 43/35

(57) ABSTRACT

A semiconductor memory device capable of reducing the chip size is provided. A semiconductor memory device includes first and second planes of memory cell arrays, first and second sense amplifiers connected to first and second bit lines connected to the first and second planes respectively. The semiconductor memory device further includes a latch circuit array connected to both the first and second sense amplifier and configured to store data to or from the first plane and data to or from the second plane.

### CROSS-REFERENCE TO RELATED APPLICATIONS

This application is based upon and claims the benefit of priority from Japanese Patent Application No. 2024-041212, filed Mar. 15, 2024, the entire contents of which are incorporated herein by reference.

### FIELD

Embodiments described herein relate generally to a semiconductor memory device.

### BACKGROUND

In recent years, memory systems including a non-volatile memory have been widely used. In the memory systems, for example, a NAND flash memory is used as a non-volatile memory. In such memory systems, efforts are being made to reduce the chip size of the non-volatile memory.

### BRIEF DESCRIPTION OF THE DRAWINGS

FIG. 1 is a block diagram illustrating configurations of a memory system and a host according to an embodiment.

FIG. 2 is a block diagram illustrating a configuration of the memory system including a semiconductor memory device according to the embodiment.

FIG. 3 is a schematic diagram illustrating a flat-surface layout of main elements in the semiconductor memory device according to the embodiment.

FIG. 4 is a perspective view diagram illustrating a configuration of a memory cell array in the semiconductor memory device according to the embodiment.

FIG. 5 is a cross-sectional diagram illustrating a configuration of a memory cell in the semiconductor memory device according to the embodiment.

FIG. 6 is a circuit diagram illustrating a configuration of a part of the memory cell array in the semiconductor memory device according to the embodiment.

FIG. 7 is a circuit diagram illustrating an example of configurations of a sense amplifier and a latch circuit in the semiconductor memory device according to the embodiment.

FIG. 8 is a diagram illustrating a flowchart of a program operation of the semiconductor memory device according to the embodiment.

FIG. 9 is a table illustrating possible combinations of activated planes at the time of the program operation of the semiconductor memory device according to the embodiment.

FIG. 10 is a diagram illustrating a flowchart of a read operation of the semiconductor memory device according to the embodiment.

FIG. 11 is a circuit diagram illustrating an example of configurations of a sense amplifier and a latch circuit in a semiconductor memory device according to another embodiment.

FIG. 12 is a diagram illustrating combinations of activated planes at the time of a program operation of a semiconductor memory device according to another embodiment.

FIG. 13 is a circuit diagram illustrating an example of configurations of a sense amplifier and a latch circuit in a semiconductor memory device according to still another embodiment.

FIG. 14 is a circuit diagram illustrating an example of configurations of a sense amplifier and a latch circuit in a semiconductor memory device according to still another embodiment.

FIG. 15 is a block diagram illustrating planes, sense amplifiers, and latch circuits in a semiconductor memory device according to still another embodiment.

### DETAILED DESCRIPTION

A semiconductor memory device capable of reducing the chip size is provided.

In general, according to an embodiment, a semiconductor memory device includes a first plane of memory cell array, a second plane of memory cell array, a first sense amplifier, a second sense amplifier, and a latch circuit array. The first plane of memory cell array includes a first memory cell string and a first bit line connected to the first memory cell string. The second plane of memory cell array includes a second memory cell string and a second bit line connected to the second memory cell string. The first sense amplifier is connected to the first bit line, and configured to perform sensing of first read data that are read from a memory cell in the first memory cell string via the first bit line and apply voltages corresponding to first write data that are to be written to a memory cell in the first memory cell string, to the first bit line. The second sense amplifier is connected to the second bit line, and configured to perform sensing of second read data that are read from a memory cell in the second memory cell string and apply voltages corresponding to second write data that are to be written to a memory cell in the second memory cell string, to the second bit line. The latch circuit array is connected to the first sense amplifier and the second sense amplifier and configured to store the first read data, the first write data, the second read data, and the second write data.

Hereinafter, a memory system of each embodiment will be described with reference to the drawings. In the following description, components having the same or similar functions and configurations will be denoted by common reference numerals. When a plurality of components having a common reference numeral are to be distinguished, subscripts (for example, capital letters of the alphabet, numbers, hyphens, capital letters of the alphabet and numbers, or the like) are added to the common reference numeral for distinguishing them, and an overlapping description may be omitted.

### First Embodiment

### 1-1. General Configuration of Memory System 3

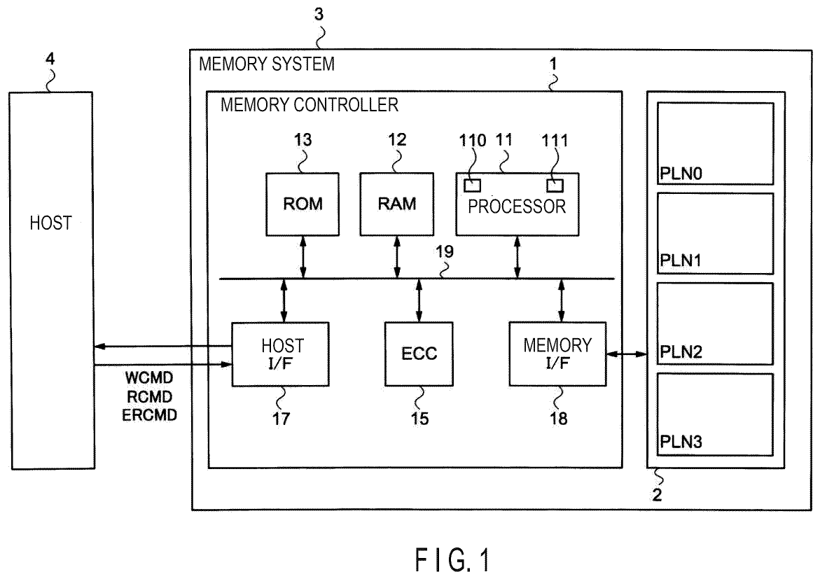

Referring to FIG. 1, a general configuration of a memory system 3 will be described. FIG. 1 is a block diagram for describing a configuration of the memory system 3. The memory system 3 includes a non-volatile memory 2, and a memory controller 1 that controls the non-volatile memory 2.

The memory system 3 may be, for example, a memory card, such as an SD™ card, in which the memory controller 1 and the non-volatile memory 2 are configured as one package, may be a UFS (Universal Flash Storage), or may be an SSD (Solid State Drive).

The memory system 3 is connected to the host 4. The host 4 is, for example, an electronic device such as a personal computer or a mobile terminal. The host 4 controls the memory system 3. The host 4 includes, for example, a processor and a memory. The processor is configured to execute various programs that are loaded to the memory. The various programs include, for example, a file system, an application, and the like that are implemented in an operating system (OS). The application is configured to, for example, exchange data (may be referred to as actual data) with the memory system 3 via the OS. The actual data is saved as file data.

The non-volatile memory 2 is a non-volatile memory that stores data in a non-volatile manner. The non-volatile memory 2 is, for example, a NAND flash memory (hereinafter simply referred to as a NAND memory). Although a case is illustrated in which a NAND memory is used as the non-volatile memory 2 in the memory system 3, a non-volatile memory other than the NAND memory, such as a three-dimensional structure flash memory, a ReRAM (Resistance Random Access Memory), or a FeRAM (Ferroelectric Random Access Memory), can be used as the non-volatile memory 2. Various storage media can be applied to the memory system 3.

Actual data transmitted from the host 4, various kinds of management tables for managing the non-volatile memory 2, management information of the memory system 3, firmware, and the like are stored in the non-volatile memory 2. The management tables include, for example, a logical address/physical address conversion table. In the logical address/physical address conversion table, a logical address of data received from the host 4 is associated with a physical address indicating a page on the non-volatile memory 2 in which the data is stored. The logical address/physical address conversion table is commonly referred to as an L2P table. The management information includes an application ID, a timestamp, logical addresses, physical addresses, page numbers that are included in the logical address/physical address conversion table, and the like. The firmware operates a processor 11 that controls at least a part of the functions of the memory controller 1. A part of the firmware may be stored in a ROM 13.

The memory controller 1 controls the non-volatile memory 2. Specifically, the memory controller 1 performs write operations, read operations, and erase operations of data on the non-volatile memory 2.

The non-volatile memory 2 includes a plurality of planes PLN (PLN0, PLN1, PLN2, PLN3). The plane PLN is a unit for performing write operations and read operations of data. In the present embodiment, the non-volatile memory 2 includes the four planes PLN0, PLN1, PLN2, and PLN3. However, the planes PLN are not limited to this, and the number of the planes PLN may be two, or may be an even number other than four.

The plane PLN includes a memory cell array 21, and the memory cell array 21 includes a plurality of blocks BLK (BLK0, BLK1, BLK3, . . . . Here, when the plurality of BLK0, BLK1, BLK3, . . . are not distinguished, they are referred to as the block BLK). Each block BLK includes a plurality of memory cell transistors that store data in a non-volatile manner. The block BLK is an erasing unit of data. The data stored in the memory cell transistors included in the same block BLK is collectively erased. All the memory cell transistors provided in the block BLK are connected to the same source line. One unit of the block BLK may be referred to as a “physical block.”

In a NAND memory, generally, write operations and read operations are performed in data units called “pages”, and erasing is performed in data units of physical blocks described above. In the memory system 3, the memory cell transistor, which is the smallest unit of a memory device, may be simply referred to as a “memory cell”, and the position of the memory cell in a physical block may be referred to as a “physical address.” Additionally, in the memory system 3, a “page” means the smallest unit of a write operation. When each memory cell is used as an SLC (Single Level Cell), a predetermined group of memory cells in one physical block corresponds to one page. When each memory cell is used as a multi-bit cell, such as an MLC (Multi Level Cell) in 2 bit (2² ways, four values) of data is stored, a TLC (Triple Level Cell) in which 3 bit (2³ ways, eight values) of data is stored, or a QLC (Quad Level Cell) in which 4 bit (2⁴ ways, 16 values) of data is stored, the predetermined group of memory cells in one physical block corresponds to a plurality of pages (i.e., two pages for MLC, three pages for TLC, and four pages for QLC). Data of the plurality of pages can be stored by setting a threshold voltage of each memory cell to one of multi-bit threshold voltages. Each memory cell is connected to both a word line and a bit line. Accordingly, each memory cell can be identified by using the address identifying a word line, and the address identifying a bit line.

### 1-2. Configuration of Memory Controller 1

The memory controller 1 is, for example, a semiconductor integrated circuit configured as an SoC (System On a Chip).

The memory controller 1 performs a write operation to the non-volatile memory 2 according to a write request from the host 4, performs a read operation from the non-volatile memory 2 according to a read request from the host 4, and performs an erase operation to the non-volatile memory 2 according to an erasing request from the host 4. The memory controller 1 includes function blocks, such as a host interface (host I/F) 17, a RAM 12, a ROM 13, the processor 11, an ECC 15, and a memory interface (memory I/F) 18. These functional blocks are connected to each other by an internal bus 19.

The host I/F 17 receives the write request, the read request, or the erase request from the host 4, and performs processing according to an interface standard between the host 4 and the host I/F 17. The host I/F 17 transmits data read from the non-volatile memory 2 to the host 4, and transmits a response from the processor 11 and the like to the host 4. It is noted that the write request includes, for example, a write command WCMD, a write address, and write data. The read request includes, for example, a read command RCMD and a read address. The erase request includes, for example, an erase command ERCMD and an erase address.

The interface standard may be, for example, the small computer system interface (SCSI), or may be the Serial SCSI (SAS) interface. In addition, the interface standard may be a high-speed communication standard, such as the Universal Serial Bus (USB), the advanced technology attachment (ATA), or the serial ATA.

The RAM 12 is used as, for example, a data buffer, and temporarily holds data received by the memory controller 1 from the host 4 until the data is stored in the non-volatile memory 2. The RAM 12 temporarily holds data read from the non-volatile memory 2 until the data is transmitted to the host 4. In addition, in the RAM 12, the L2P table and the like that are read from the non-volatile memory 2 in accordance with each command are developed. A general-purpose memory, such as an SRAM (Static Random Access Memory) or a DRAM (Dynamic Random Access Memory), can be used as the RAM 12.

The ROM 13 stores various programs, parameters, and the like for operating the memory controller 1. The programs, the parameters, and the like that are stored in the ROM 13 are read and executed by the processor 11 according to need.

The processor 11 is a control unit that comprehensively controls each of the function blocks of the memory system 3. The processor 11 includes a data management unit 110 and a write/read (W/R) management unit 111. The functions of the data management unit 110 may be achieved by hardware, or may be achieved by a CPU that executes the firmware. The functions of the W/R management unit 111 may be achieved by hardware, or may be achieved by the CPU that executes the firmware. When the processor 11 accepts a request (e.g., write request, read request, or erase request) from the host 4 via the host I/F 17, the processor 11 performs control (e.g., generates instructions) according to the request by using the data management unit 110 and the W/R management unit 111.

The memory I/F 18 executes write operations, read operations, and erase operations on the non-volatile memory 2 in accordance with an instruction from the processor 11.

For example, according to a write request from the host 4, the processor 11 instructs the memory I/F 18 to perform a write operation of data on the non-volatile memory 2. For example, according to the write request from the host 4, the data management unit 110 determines, by using the LAP table, a write destination on the non-volatile memory 2 (the physical address indicating a page in the non-volatile memory 2) for data that is to be written and that is temporarily held by the RAM 12. That is, the data management unit 110 manages the data to be written, and the write destination of the data. In addition, the W/R management unit 111 receives the physical address from the data management unit 110, and instructs the memory I/F 18 to perform the write operation for writing the data to be written to the physical address. The memory I/F 18 outputs the data to be written and the physical address to the non-volatile memory 2, and the data to be written is stored in the page of the non-volatile memory 2 corresponding to the physical address.

In addition, the processor 11 instructs the memory I/F 18 to perform a read operation of data from the non-volatile memory 2 according to a read request from the host 4. For example, according to the read request from the host 4, the data management unit 110 determines, by using the L2P table, the physical address indicating the page in the non-volatile memory 2 corresponding to the logical address of the data to be read. That is, the data management unit 110 manages the logical address of the data to be read, and the physical address corresponding to the logical address by using the L2P table. In addition, the W/R management unit 111 receives the physical address from the data management unit 110, and instructs the memory I/F 18 to perform a read operation for reading the data to be read from the physical address. The memory I/F 18 outputs the data to be read and the physical address to the non-volatile memory 2, and reads the data to be read from the physical address.

In addition, the processor 11 instructs the memory I/F 18 to perform an erase operation of data to the non-volatile memory 2 according to an erase request from the host 4. For example, according to the erase request from the host 4, the data management unit 110 determines, by using the L2P table, the physical address indicating the page in the non-volatile memory 2 corresponding to the logical address of the data to be erased. That is, the data management unit 110 manages the logical address of data to be erased, and the physical address corresponding to the logical address. In addition, the W/R management unit 111 receives the physical address from the data management unit 110, and instructs the memory I/F 18 to perform an erase operation for erasing the data to be erased from the physical address. The memory I/F 18 outputs the data to be erased and the physical address to the non-volatile memory 2, and erases the data to be erased from the physical address.

In addition, the data management unit 110 executes garbage collection (GC), and an application based optimization (ABO) process.

The garbage collection (GC) is a process for increasing available blocks among physical blocks, and means, for example, a process of collecting valid data from a plurality of active blocks in which the valid data and invalid data are included, rewriting the valid data to another block, and securing free blocks. Here, an active block refers to a physical block in which valid data is stored. A free block refers to a physical block in which valid data is not stored. A free block can be reused as an erased block after erasing. Free blocks include both blocks before erasing in which valid data is not stored, and erased blocks. Valid data is data associated with a logical address described later, and invalid data is data not associated with a logical address. An erased block becomes an active block when data is written to the erased block. For example, the data management unit 110 counts the number of free blocks, and when the number of free blocks is equal to or less than a predetermined threshold value, the data management unit 110 executes the GC. When the number of free blocks is larger than the predetermined threshold value, the data management unit 110 does not need to execute the GC processing.

In addition, the application based optimization (ABO) process means a process of storing a plurality of items of application data corresponding to continuous logical addresses generated by using the same application in the physical blocks corresponding to the continuous physical addresses of the non-volatile memory 2 in the order of the corresponding logical addresses, respectively.

The ECC 15 executes ECC coding (error correction coding) at the time of a write operation, and ECC decoding (error correction decoding) at the time of a read operation, in accordance with instructions from the processor 11. As the coding scheme of the ECC 15, for example, a coding scheme using LDPC (Low-Density Parity-Check) coding, BCH (Bose-Chaudhuri-Hocquenghem) coding, or RS (Reed-Solomon) coding can be employed.

### 1-3. Configuration of Non-Volatile Memory 2

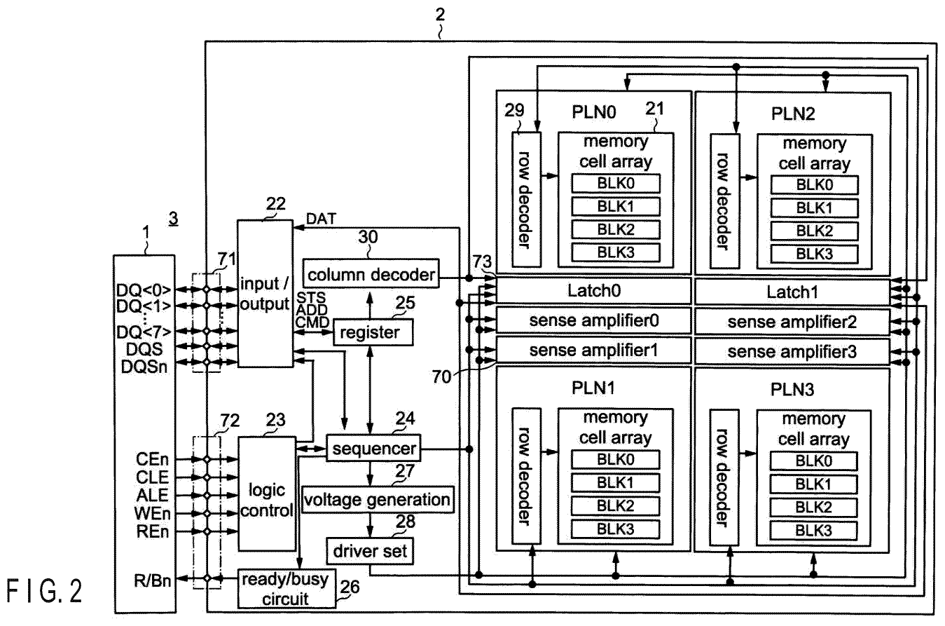

Referring to FIG. 2, a general configuration of the non-volatile memory 2 will be described. FIG. 2 is a block diagram for describing a configuration of the memory system 3 including the non-volatile memory 2. As illustrated in FIG. 2, the non-volatile memory 2 includes an input/output circuit 22, a logic control circuit 23, a sequencer 24, a register 25, a ready/busy control circuit (26, a voltage generation circuit 27, a driver set 28, a plurality of sense amplifier modules 70, an input/output pad group 71, a logic control pad group 72, a plurality of latch circuit units 73, and a plurality of planes PLN. Each of the plurality of planes PLN includes the memory cell array 21 and a row decoder 29. In the non-volatile memory 2, various kinds of operations, such as a write operation for storing write data DAT in the memory cell array 21, and a read operation for reading read data DAT from the memory cell array 21, are executed.

It is noted that partial elements of the input/output circuit 22, the logic control circuit 23, the sequencer 24, the register 25, the ready/busy control circuit 26, the voltage generation circuit 27, the driver set 28, the plurality of row decoders 29, the plurality of sense amplifier modules 70, and the plurality of latch circuit units 73 may be referred to as a control circuit.

Each memory cell array 21 is connected to, for example, a corresponding one of the sense amplifier modules 70, a corresponding one of the row decoders 29, and the driver set 28. For example, the memory cell array 21 of the plane PLN0 is connected to a sense amplifier 0, the memory cell array 21 of the plane PLN1 is connected to a sense amplifier 1, the memory cell array 21 of the plane PLN2 is connected to a sense amplifier 2, and the memory cell array 21 of the plane PLN3 is connected to a sense amplifier 3 (Here, when the sense amplifier 0, the sense amplifier 1, the sense amplifier 2, and the sense amplifier 3 are not distinguished, each is referred to as the sense amplifier module 70.). The memory cell array 21 of the plane PLN0 is connected to the row decoder 29 of the plane PLN0, the memory cell array 21 of the plane PLN1 is connected to the row decoder 29 of the plane PLN1, the memory cell array 21 of the plane PLN2 is connected to the row decoder 29 of the plane PLN2, and the memory cell array 21 of the plane PLN3 is connected to the row decoder 29 of the plane PLN3.

Further, the plurality of sense amplifier modules 70 are connected to the common latch circuit unit 73. For example, the sense amplifier 0 and the sense amplifier 1 are commonly connected to a Latch0, and the sense amplifier 2 and the sense amplifier 3 are commonly connected to a Latch1 (Here, when the Latch0 and the Latch are not distinguished, each is called the latch circuit unit 73.). In the present embodiment, since the two sense amplifier modules 70 are commonly connected to the same latch circuit unit 73, the size of peripheral circuits can be reduced by an area for one latch circuit unit 73. Therefore, the chip size of the non-volatile memory 2 can be reduced, and the manufacturing cost can be reduced by increasing the number of chips that can be obtained per wafer.

The input/output circuit 22 is connected to, for example, the register 25, the logic control circuit 23, and the sense amplifier module 70. The input/output circuit 22 can be connected to the memory controller 1, and controls transmission and reception of a data signal DQ<7:0> and clock signals DQS and DQSn between the memory I/F 18 included in the memory controller 1 and the non-volatile memory 2.

The signal DQ<7:0> is the entity of data transmitted and received between the non-volatile memory 2 and the memory I/F 18 included in the memory controller 1. The signal DQ<7:0> includes a command CMD, data DAT, address information ADD, status information STS, and the like. The clock signals DOS and DQSn are clock signals used at the time of input and output of data. The clock signal DQSn is the inverted signal of the clock signal DQS.

The command CMD includes, for example, a command for executing a request transmitted from the host 4 to the non-volatile memory 2 via the memory I/F 18 included in the memory controller 1. The data DAT includes write data DAT to the non-volatile memory 2, or read data DAT from the non-volatile memory 2. The data DAT includes, for example, Edata. Here, Edata is the encoded data which the ECC 15 generates. The processor 11 instructs the ECC 15 to encode data to be written to the non-volatile memory 2. The ECC 15 encodes the data to be written to the non-volatile memory 2 and generates Edata which is the encoded data. The address information ADD includes, for example, column addresses and row addresses for selecting a plurality of non-volatile memory cells associated with bit lines and word lines. The status information STS includes, for example, information about the status of the non-volatile memory 2 regarding a write operation and a read operation.

Specifically, the input/output circuit 22 includes an input circuit and an output circuit, and the input circuit and the output circuit perform processing describe below. The input circuit receives the write data DAT, the address information ADD, and the command CMD from the memory controller 1. The input circuit transmits the write data DAT received in accordance with an instruction of the sequencer 24 to the latch circuit unit 73 of the corresponding plane PLN, and transmits the address information ADD and the command CMD received in accordance with the instruction from the sequencer 24 to the register 25. On the other hand, the output circuit receives the status information STS from the register 25, and receives read data DAT from the latch circuit unit 73 of the corresponding plane PLN. The output circuit transmits the received status information STS and read data DAT to the memory I/F 18 included in the memory controller 1.

The logic control circuit 23 is connected to, for example, the memory controller 1, the input/output circuit 22, and the sequencer 24. The logic control circuit 23 receives, for example, a chip enable signal CEn, a command latch enable signal CLE, an address latch enable signal ALE, a write enable signal WEn, and a read enable signal REn via the memory I/F 18 of the memory controller 1. The logic control circuit 23 controls the input/output circuit 22 and the sequencer 24 in accordance with the received signals.

The chip enable signal CEn is a signal for enabling the non-volatile memory 2, and is asserted at, for example, a Low (“L”) level. The command latch enable signal CLE is a signal indicating that the signal DQ<7:0> is a command, and is asserted at, for example, a High (“H”) level. The address latch enable signal ALE is a signal indicating that the signal DQ<7:0> is an address, and is asserted at, for example, the “H” level.

The write enable signal WEn is a signal for loading the received signals into the non-volatile memory 2. The signal WEn is asserted at, for example, the “L” level at the timing when the non-volatile memory 2 loads the command and the address. Thus, each time the signal WEn is toggled, the command and the address are loaded in the non-volatile memory 2.

The read enable signal REn is a signal for the memory controller 1 to read data from the non-volatile memory 2. The signal REn is asserted at, for example, the “L” level. For example, the non-volatile memory 2 generates the signals DQS and DQSn in accordance with the signal REn when outputting data.

The sequencer 24 is connected to, for example, the ready/busy control circuit 26, the sense amplifier module 70, and the driver set 28. The sequencer 24 controls the entire operation of the non-volatile memory 2 in accordance with the command CMD held by a command register. For example, the sequencer 24 controls the sense amplifier module 70, the row decoder 29, the voltage generation circuit 27, the driver set 28, and the like to execute various kinds of operations such as a write operation, a read operation, and an erase operation.

The register 25 includes, for example, a status register (illustration is omitted), an address register (illustration is omitted), a command register (illustration is omitted), and the like. The status register receives and holds the status information STS from the sequencer 24. The status information STS is transmitted to the input/output circuit 22 in accordance with an instruction from the sequencer 24. The address register receives and holds the address information ADD from the input/output circuit 22. The column address in the address information ADD is transmitted to a column decoder 30 in accordance with an instruction from the sequencer 24, and the row address in the address information ADD is transmitted to the row decoder 29 of the corresponding plane PLN. The command register receives and holds the command CMD from the input/output circuit 22. The command CMD is transmitted to the sequencer 24 in accordance with an instruction from the sequencer 24.

The ready/busy control circuit 26 generates a ready/busy signal R/Bn according to control by the sequencer 24, and transmits the generated ready/busy signal R/Bn to the memory controller 1. The ready/busy signal R/Bn is a signal for notifying whether the non-volatile memory 2 is in a ready state in which the non-volatile memory 2 receives the signal DQ<7:0> from the memory controller 1, or in a busy state in which the non-volatile memory 2 does not receive the signal DQ<7:0>. For example, the ready/busy signal R/Bn is at the “L” level when the non-volatile memory 2 is in the busy state.

The voltage generation circuit 27 is connected to, for example, the driver set 28 and the like. The voltage generation circuit 27 generates a voltage used for a write operation, a read operation, or the like based on control by the sequencer 24, and supplies the generated voltage to the driver set 28.

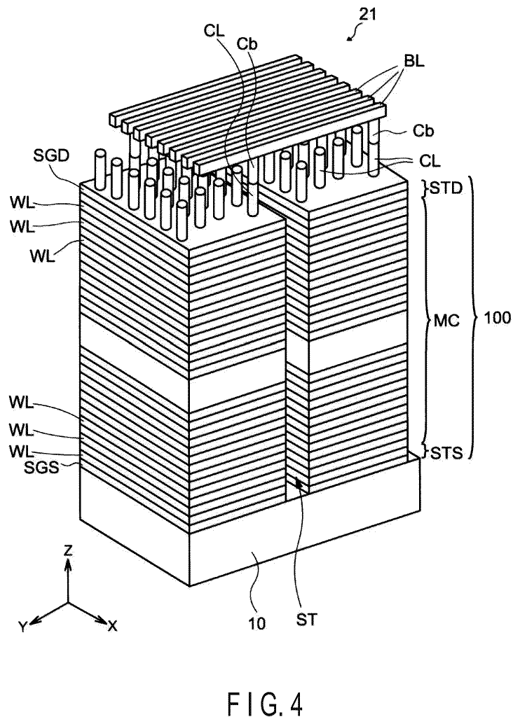

The driver set 28 is connected to the memory cell arrays 21, the sense amplifier module 70, and the row decoders 29. Based on the voltages supplied from the voltage generation circuit 27, or a control signal supplied from the sequencer 24, the driver set 28 generates, for example, various levels of voltages or various kinds of control signals supplied to a selection gate line SGD (FIG. 4), word lines WL (FIG. 4), a source line SL (FIG. 4), bit lines BL (FIG. 4), and the like in various kinds of operations such as a read operation and a write operation. The driver set 28 supplies the generated voltages or control signals to the sense amplifier module 70, the row decoders 29, the source line SL, and the like.

The row decoder 29 receives the row address from the address register, and decodes the received row address. The row decoder 29 selects, based on the result of the decoding, the block BLK on which various kinds of operations such as a read operation and a write operation are to be executed. The row decoder 29 can supply the voltage supplied from the driver set 28 to the selected block BLK.

The column decoder 30 receives the column address from the address register, and decodes the received column address. The column decoder 30 selects the latch circuit in the corresponding latch circuit unit 73 based on the result of the decoding.

The sense amplifier module 70 is connected to, for example, the latch circuit in the latch circuit unit 73 selected based on the column address, and executes transmission and reception operations of the data DAT between the memory controller 1 and the memory cell array 21. In addition, the sense amplifier module 70 can sense the data (threshold value voltage) read from the memory cell array 21 in accordance with an instruction related to a read operation, and can temporarily hold the read data (threshold value voltage) in the latch circuit unit 73. In addition, the sense amplifier module 70 can perform a logical operation based on the data temporarily saved in the latch circuit unit 73. In addition, the sense amplifier module 70 transmits the data (read data) DAT that has been read to the memory controller 1 via the input/output circuit 22. Further, the sense amplifier module 70 receives write data DAT from the memory controller 1 via the input/output circuit 22 in accordance with an instruction related to a write operation, and transmits the write data DAT to the memory cell array 21.

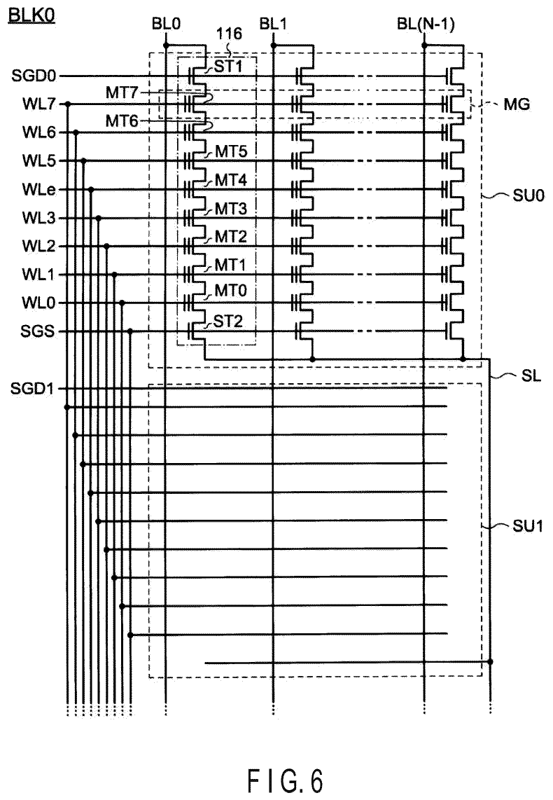

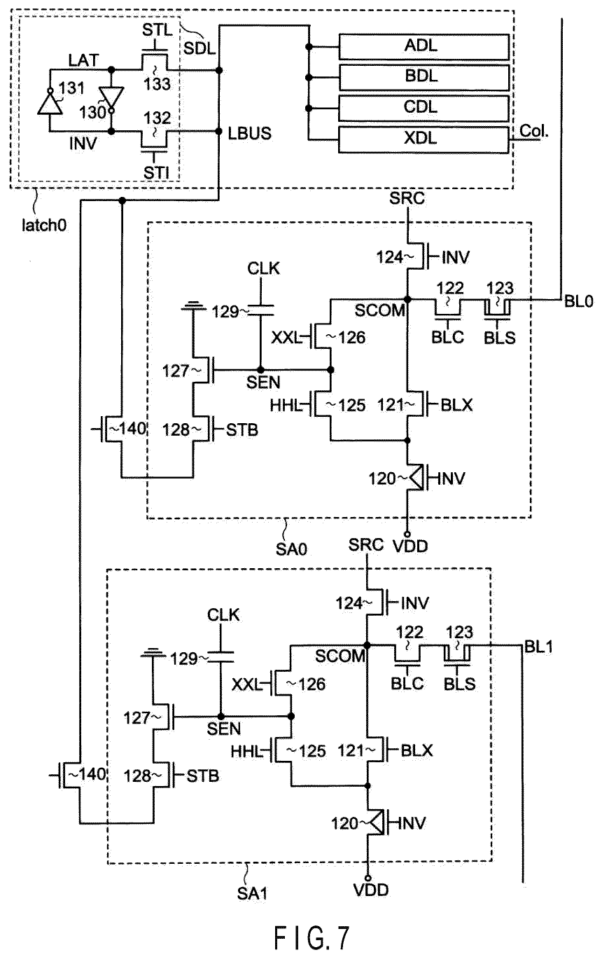

The sense amplifier module 70 includes, for example, a plurality of sense amplifiers SA (FIG. 7, a sense amplifier SA0, a sense amplifier SA1 . . . . Here, when the plurality of sense amplifier SA0, sense amplifier SA1 . . . are not distinguished, they are referred to as the sense amplifier SA) provided for each bit line BL (BL0, BL1, . . . , BL(N−1), where (N—1) is a natural number of two or more. Here, when the plurality of BL0, BL1, . . . , BL(N−1) are not distinguished, they are referred to as the bit line BL. FIG. 6). The sense amplifiers SA are electrically connected to the bit line BL so as to be able to supply voltage.

In the present embodiment, the non-volatile memory 2 includes TLC (3 bit/Cell) memory cell transistors MT, and although details will be described later, the number of latch circuits that store program data (for example, EData) connected to the sense amplifiers SA is three. Each latch circuit temporarily stores write data or read data.

The input/output pad group 71 transmits the signal DQ<7:0> received from the memory controller 1 to the input/output circuit 22. The input/output pad group 71 transmits the signal DQ<7:0> received from the input/output circuit 22 to the memory controller 1. The logic control pad group 72 transfers, to the logic control circuit 23, the chip enable signal CEn, the command latch enable signal CLE, the address latch enable signal ALE, the write enable signal WEn, and the read enable signal REn that are received from the memory controller 1. The logic control pad group 72 transfers the ready/busy signal R/Bn received from the ready/busy control circuit 26 to the memory controller 1.

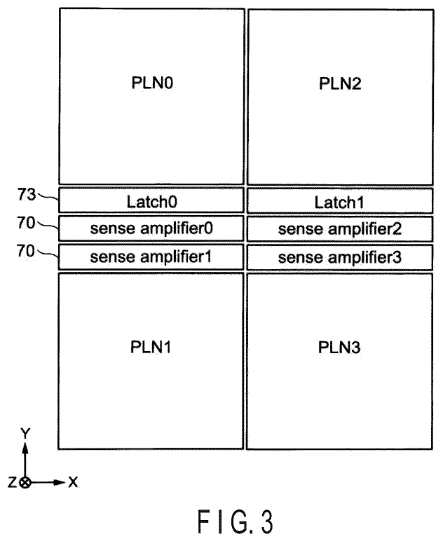

FIG. 3 is a schematic diagram illustrating a flat-surface layout of main elements in the non-volatile memory 2. As illustrated in FIG. 3, in the plan view, two sense amplifier modules 70 commonly connected to the same latch circuit unit 73 and this latch circuit unit 73 are arranged between the two corresponding planes PLN. For example, the sense amplifier 0, the sense amplifier 1, and the Latch0 are arranged between the plane PLN0 and the plane PLN1, and the sense amplifier 2, the sense amplifier 3, and the Latch1 are arranged between the plane PLN2 and the plane PLN3. In the present embodiment, since the two sense amplifier modules 70 and the one latch circuit unit 73 are arranged between the two planes PLN to which they are to be connected, connection can be efficiently made.

In FIG. 3, the latch circuit unit 73 is arranged adjacent to the plane PLN to which the latch circuit unit 73 is connected. For example, the plane PLN0, the Latch0, the sense amplifier 0, the sense amplifier 1, and the plane PLN1 are arranged in this order, and the plane PLN2, the Latch1, the sense amplifier 2, the sense amplifier 3, and the plane PLN3 are arranged in this order. However, the latch circuit unit 73 is not be limited to this arrangement, and the latch circuit unit 73 may be arranged between the two sense amplifier modules 70 connected thereto.

### 1-4. Configuration of Memory Cell Array 21

Using FIG. 4, a configuration of the memory cell array 21 will be described. FIG. 4 is a schematic perspective view diagram illustrating the arrangement of each element of the memory cell array 21 according to the present embodiment.

An X direction, a Y direction, and a Z direction illustrated in FIG. 4 correspond to an X direction, a Y direction, and a Z direction illustrated in FIG. 3. In FIG. 4, two directions that are directions parallel to a principal surface of a substrate 10 and that are orthogonal to each other are called the X direction and the Y direction, and a surface parallel to the principal surface of the substrate 10 is referred to as an XY surface. A direction that is orthogonal to both of these X direction and Y direction is called the Z direction (lamination direction).

As illustrated in FIG. 4, the memory cell array 21 includes the substrate 10, a laminated body 100 provided on the substrate 10, a plurality of columnar body units CL, and a plurality of bit lines BL provided above the laminated body 100.

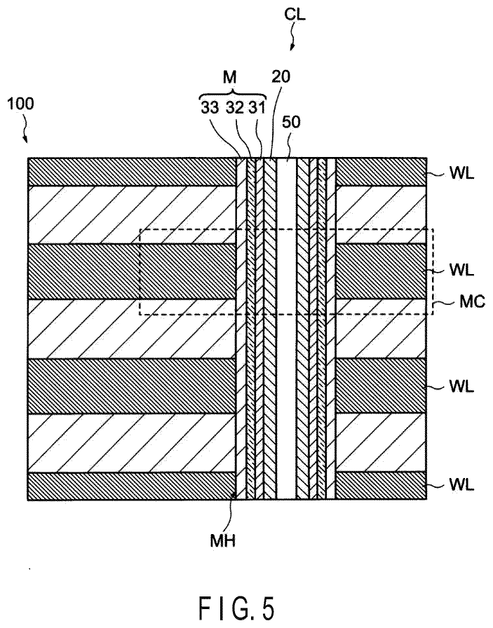

In the laminated body 100, a plurality of conductive layers that are insulated from each other, and periodically laminated in the direction (lamination direction) perpendicular to the principal surface of the substrate 10 are formed, and the plurality of conductive layers correspond to the selection gate line SGS, the plurality of word lines WL, and the selection gate line SGD from the substrate side. Openings ST and MH are formed in the laminated body 100. The openings ST and MH extend in the lamination direction (Z direction), and penetrate the laminated body 100 to reach the substrate 10. The opening ST extends in the X direction, and separates the laminated body 100 into a plurality of blocks in the Y direction. The columnar body units CL are formed in the opening MH (refer to FIG. 5).

The columnar body units CL are formed into columns that extend in the lamination direction in the laminated body 100. The plurality of columnar body units CL are disposed in, for example, a staggered manner. Alternatively, the plurality of columnar body units CL may be disposed in a square grid along the X direction and the Y direction.

The plurality of bit lines BL are separated from each other in the X direction, and each of the bit lines BL extends in the Y direction.

An upper end of a semiconductor layer 20 (refer to FIG. 5), which will be described later, of the columnar body unit CL is connected to the bit line BL via a contact portion Cb. The plurality of columnar body units CL, each one being selected from each of the blocks separated in the Y direction by the opening ST, are connected to one common bit line BL.

It is noted that an insulating layer is formed between the word line WL and the word line WL that are adjacent to each other in the lamination direction. An insulating layer is formed in slit ST, and an insulating layer is formed on the laminated body 100. However, these insulating layers are omitted in FIG. 4 for convenience of description.

FIG. 5 is a cross-sectional diagram illustrating a configuration of the memory cell according to the present embodiment. FIG. 5 illustrates an enlarged cross-sectional view of the columnar body unit CL in FIG. 4.

As illustrated in FIG. 5, the columnar body unit CL is a structure that includes a memory layer M, the semiconductor layer 20, and an insulating core layer 50. The semiconductor layer 20 continuously extends in the lamination direction (Z direction) in the laminated body 100. The material of the semiconductor layer 20 includes, for example, amorphous or polycrystalline silicon. The core layer 50 is provided inside the cylindrical semiconductor layer 20. The material of the core layer 50 includes, for example, silicon oxide. The memory layer M is provided between the word line WL and the semiconductor layer 20. The memory layer M surrounds the semiconductor layer 20 from the outer-circumference side of the semiconductor layer 20.

The memory layer M includes a tunnel insulating layer 31, an electric charge accumulation layer 32, and a block insulating layer 33 (Here, when the tunnel insulating layer 31, the electric charge accumulation layer 32, and the block insulating layer 33 are not distinguished, they are referred to as the memory layer M). The block insulating layer 33, the electric charge accumulation layer 32, and the tunnel insulating layer 31 continuously extend in the lamination direction of the laminated body 100 with the semiconductor layer 20. The block insulating layer 33, the electric charge accumulation layer 32, and the tunnel insulating layer 31 are provided in this order from the word line WL side between the word line WL and the semiconductor layer 20. The tunnel insulating layer 31 contacts the semiconductor layer 20. The block insulating layer 33 contacts the word line WL. The electric charge accumulation layer 32 is provided between the block insulating layer 33 and the tunnel insulating layer 31.

The semiconductor layer 20, the memory layer M, and the word line WL form a memory cell MC. In FIG. 5, one memory cell MC is schematically indicated by broken lines. The memory cell MC has a vertical transistor structure in which the word line WL surrounds the circumference of the semiconductor layer 20 via the memory layer M.

In the memory cell MC having the vertical transistor structure, the semiconductor layer 20 functions as a channel, and the word line WL functions as a control gate of the memory cell. The electric charge accumulation layer 32 functions as a data layer that accumulates electric charges injected from the semiconductor layer 20.

As described above, a plurality of memory cells MC are arranged in the lamination direction of the plurality of word lines WL, and the plurality of word lines WL are connected to the plurality of memory cells MC, respectively. The word line WL in the vicinity of the block insulating layer 33 functions as the control gate. By controlling the voltage to the word line WL connected to memory cell MC, writing to or erasing from the memory cell MC can be controlled. The semiconductor memory device according to the present embodiment is a non-volatile semiconductor device capable of electrically and freely performing writing of data to or erasing of data from the memory cell MC, and capable of storing the content even when the power is turned off.

The memory cell MC is, for example, a charge-trap memory cell. The electric charge accumulation layer 32 has a large number of trap sites that capture electric charges in an insulating layer. The material of the electric charge accumulation layer 32 includes, for example, silicon nitride.

When electric charges are injected into the electric charge accumulation layer 32 from the semiconductor layer 20, or when electric charges accumulated in the electric charge accumulation layer 32 diffuse toward the semiconductor layer 20, the tunnel insulating layer 31 serves as a potential barrier. The material of the tunnel insulating layer 31 includes, for example, silicon oxide.

The block insulating layer 33 prevents the electric charges accumulated in the electric charge accumulation layer 32 from diffusing to the word line WL. The material of the block insulating layer 33 includes, for example, silicon oxide.

FIG. 6 is a circuit diagram of the block BLK included in the memory cell array 21 of the non-volatile memory 2. Although a description will be given by taking the block BLK0 as an example, the other blocks BLK1, 2, . . . also have the same circuit. It is noted that the circuit diagram illustrated in FIG. 6 is an example, and does not limit the circuit diagram of the memory cell array 21 of the first embodiment. In the description of the memory cell array 21, a description of configurations that are the same as or similar to the configurations in FIG. 1 to FIG. 5 may be omitted.

The block BLK0 includes N bit lines BL (BL0, BL1, . . . , BL(N−1) (N is an integer of two or more)) arranged in columns, and a plurality of NAND strings 116 and the source line SL arranged in a matrix. The NAND strings 116 are connected between the N bit lines BL and the source line SL. The NAND string 116 includes, for example, eight memory cell transistors MT (MT0 to MT7) and selection transistors ST1 and ST2. The memory cell transistors MT include a control gate and an electric charge accumulation layer, and hold data in a non-volatile manner. The memory cell transistors MT are connected in series between a source of the selection transistor ST1 and a drain of the selection transistor ST2. String units SU (SU0, SU1) are formed by providing the NAND strings 116 to the N bit lines BL. It is noted that, in FIG. 6, although the NAND string 116 includes, for example, eight memory cell transistors MT, the number of memory cell transistors MT included in the NAND string 116 is not limited to eight. For example, the number of memory cell transistors MT may be i, and the integer i may be larger than eight, or may be smaller than eight.

The selection transistor ST1 is connected to a selection gate line SGD0. Gates of the selection transistors ST1 in each of the string units SU are each connected to the selection gate line SGD (SGD0, SGD1, . . . . Here, when the plurality of SGD0, SGD1, . . . are not distinguished, they are referred to as the selection gate line SGD). Gates of the eight memory cell transistors MT (MT0 to MT7) are connected to the corresponding word lines WL (WL7 to WL0), respectively. In addition, gates of the selection transistors ST2 in each of the string units SU are connected to the selection gate line SGS. The gates of the selection transistors ST1 connected to the plurality of respective bit lines BL in the same string unit SU are connected to the common selection gate line SGD. The gates of the memory cell transistors MT (MT0 to MT7) in the same string unit SU are connected to the common word lines WL (WL0 to WL7), respectively. The gates of the plurality of selection transistors ST2 in the same block BLK are connected to the common selection gate line SGS. The source line SL is shared among, for example, the plurality of blocks BLK.

The memory cell transistors MT connected to the same word line WL (WL0 to WL7) in the same string unit SU correspond to a unit for read operation and write operation. For example, the memory cell transistor MT7 in each NAND string 116 included in the string unit SU corresponding to selection gate line SGD0 corresponds to a memory cell group MG as a unit for read operation and write operation, and a read operation and a write operation are collectively executed to the memory cell group MG. For example, when the memory cell transistors MT are TLCs, 3-page data is stored in the memory cell group MG.

### 1-5. Configuration of Sense Amplifier SA and Latch Circuit

Next, an example of configurations of the sense amplifier SA and the latch circuit will be described. FIG. 7 is a circuit diagram illustrating an example of the configurations of the sense amplifier SA and the latch circuit according to the first embodiment. It is noted that the configurations illustrated in FIG. 7 are examples, and do not limit the configurations of the sense amplifier SA and the latch circuit of the non-volatile memory according to the first embodiment. A description of the configurations that are the same as or similar to the configurations in FIG. 1 to FIG. 6 may be omitted.

FIG. 7 illustrates the circuit configuration of the sense amplifiers SA of two different sense amplifier modules 70 connected to the bit lines BL of two different planes PLN. For example, the bit line BL0 of the plane PLN0 is connected to the sense amplifier SA0 of the sense amplifier 0, and the bit line BL1 of the plane PLN1 is connected to the sense amplifier SA1 of the sense amplifier 1. However, the sense amplifiers SA are not limited to this, and for example, a plurality of bit lines BL may be connected to one sense amplifier SA via a selector.

The latch circuit unit 73 includes a plurality of latch circuit groups (may be referred to as a latch circuit array). Each of the latch circuit groups includes latch circuits SDL, ADL, BDL, CDL, and XDL. The sense amplifier SA0 and the sense amplifier SAL are each electrically connected to a latch circuit group “latch0” of the latch circuit unit Latch0 via a bus LBUS. The two sense amplifiers SA0 and SAL are connected to the latch circuit group “latch0” via respective selectors (may be referred to as switches) 140. Selection signals input to the selectors 140 are generated by, for example, the sequencer 24.

The sense amplifier SA senses the data read to the corresponding bit line BL at the time of a read operation, and determines whether the read data is “0” or “1.” The sense amplifier SA applies voltage to the bit line BL based on write data at the time of a write operation. The sense amplifier SA includes, for example, a p-channel MOS transistor 120, n-channel MOS transistors 121 to 128, and a capacitor 129.

The sense amplifier SA is connected between a power line and a node SRC. A voltage smaller than the voltage supplied to the power line is supplied to the node SRC. The power line is a voltage supply line that supplies a high-level voltage to the sense amplifier SA. The node SRC is a node that supplies a low-level voltage to the sense amplifier SA. The sense amplifier SA operates by being supplied with the voltage from the power line and the node SRC. It is noted that the power line and the node SRC may be configured to supply the voltage to elements other than the sense amplifier SA. The high-level voltage is, for example, a voltage VDD, a voltage VHSA, and the like, and the low-level voltage is, for example, a voltage VSS, a voltage SRCGND[m:0], and the like. The power line may be called a “high-voltage supply line”, a “voltage supply terminal”, or a “high-voltage supply terminal,” and the node SRC may be called a “voltage supply terminal” or a “low-voltage supply terminal.”

One end of the transistor 120 is connected to the power line, and a gate of the transistor 120 is connected to a node INV in the latch circuit SDL. One end of the transistor 121 is connected to the other end of the transistor 120, the other end of the transistor 121 is connected to a node SCOM, and a control signal BLX is input to a gate of the transistor 121. One end of the transistor 122 is connected to the node SCOM, and a control signal BLC is input to a gate of the transistor 122. The transistor 123 is a high breakdown voltage MOS transistor, one end of the transistor 123 is connected to the other end of the transistor 122, the other end of the transistor 123 is connected to the corresponding bit line BL, and a control signal BLS is input to a gate of the transistor 123. Although details will be described later, the transistor 122 receives the control signal BLC at the gate, and has a function of supplying the voltage supplied to the node SCOM to the bit line BL. The transistor 122 may be called a “control transistor.”

One end of the transistor 124 is connected to the node SCOM, the other end of the transistor 124 is connected to the node SRC, and a gate of the transistor 124 is connected to the node INV. One end of the transistor 125 is connected to the other end of the transistor 120, the other end of the transistor 125 is connected to a node SEN, and a control signal HHL is input to a gate of the transistor 125. One end of the transistor 126 is connected to the node SEN, the other end of the transistor 126 is connected to the node SCOM, and a control signal XXL is input to a gate of the transistor 126.

One end of the transistor 127 is grounded, and a gate of the transistor 127 is connected to the node SEN. One end of the transistor 128 is connected to the other end of the transistor 127, the other end of the transistor 128 is connected to the bus LBUS via the selector 140, and a control signal STB is input to a gate of the transistor 128. One end of the capacitor 129 is connected to the node SEN, and a clock CLK is input to the other end of the capacitor 129. For example, the voltage VSS is supplied to the clock CLK.

The control signals BLX, BLC, BLS, HHL, XXL, STI, STL, and STB described above are generated by, for example, the sequencer 24. In addition, for example, the voltage VDD, which is the internal power voltage of the non-volatile memory 2, or the voltage VHSA is supplied to the power line connected to the one end of the transistor 120, and for example, the voltage VSS, which is the ground voltage of the non-volatile memory 2, or the voltage SRCGND[m:0] (m is an integer of one or more) supplied to a bit line ProgramBL is supplied to the node SRC.

The latch circuits SDL, ADL, BDL, and CDL temporarily store read data or write data. For example, in the case of a read operation, read data is stored in one of the latch circuit SDL, ADL, BDL and CDL. In addition, for example, in the case of a write operation, write data of the latch circuit XDL is stored in one of the latch circuits SDL, ADL, BDL and CDL. It is noted the number of latch circuits included in the latch circuit group is designed based on the number of bits of data that can be stored in one memory cell transistor MC. When the memory cell transistor MT can save n-bit data, the number of latch circuits included in the latch circuit group may be n+2. In the present embodiment, the non-volatile memory 2 includes the TLC (3 bit/Cell) memory cell transistors MT, and the number of latch circuits included in the latch circuit group is five.

The latch circuit XDL is used as a cache memory for input and output of data between the sense amplifier SA and the input/output circuit 22. More specifically, write data received from the memory controller 1 is transmitted to the latch circuits SDL, ADL, BDL and CDL via the latch circuit XDL, or to the sense amplifier SA. In addition, read data stored in the latch circuits SDL, ADL, BDL, and CDL, or in the sense amplifier SA is transmitted to the memory controller 1 via the latch circuit XDL.

The latch circuit SDL includes, for example, inverters 130 and 131, and n-channel MOS transistors 132 and 133. An input node of the inverter 130 is connected to a node LAT, and an output node of the inverter 130 is connected to the node INV. An input node of the inverter 131 is connected to the node INV, and an output node of the inverter 131 is connected to the node LAT. One end of the transistor 132 is connected to the node INV, the other end of the transistor 132 is connected to the bus LBUS, and a control signal STI is input to a gate of the transistor 132. One end of the transistor 133 is connected to the node LAT, the other end of the transistor 133 is connected to the bus LBUS, and a control signal STL is input to a gate of the transistor 133. For example, the data held in the node LAT corresponds to the data held in the latch circuit SDL, and the data held in the node INV corresponds to the inverted data of the data held in the node LAT. Since the circuit configurations of the latch circuits ADL, BDL, CDL, and XDL are the same as, for example, the circuit configuration of the latch circuit SDL, a description thereof will be omitted.

One end of the selector 140 is connected to the other end of the transistor 128, the other end of the selector 140 is connected to the bus LBUS, and a selection signal for turning on or off the selector 140 is input to a gate of the selector 140. The selection signal input to the selector 140 is generated by, for example, the sequencer 24. Switching between the two sense amplifiers SA0 and SA1 is performed by the selection signal. Either one of the selectors 140 of the two sense amplifiers SA0 and SA1 that share the latch circuit unit 73 is turned off. However, the switching is not limited to this, and when opening and closing of the gate of the transistor 128 is linked to address selection, the selector 140 may be absent, and the other end of the transistor 128 is directly connected to the bus LBUS.

In the sense amplifiers SA described above, the timing at which each sense amplifier SA determines the data corresponding to the threshold voltage read to the bit line BL is based on the timing at which the control signal STB is asserted. In the non-volatile memory 2, “the sequencer 24 asserts the control signal STB” corresponds to that the sequencer 24 changes the control signal STB to the “H” level from the “L” level.

The configuration of the sense amplifier SA is not limited to the configuration and functions described by using FIG. 7. For example, in the sense amplifier SA, the transistor 128 to whose gate the control signal STB is input may be configured with a p-channel MOS transistor. In this case, “the sequencer 24 asserts the control signal STB” corresponds to that the sequencer 24 changes the control signal STB from the “H” level to the “L” level.

Since the circuit configurations of the bit line BL of the plane PLN2, the sense amplifier SA of the sense amplifier 2, the bit line BL of the plane PLN3, the sense amplifier SA of the sense amplifier 3, and the latch circuit group of the latch circuit unit Latch1 are the same as the circuit configurations of the bit line BL0 of the plane PLN0, the sense amplifier SA0 of the sense amplifier 0, the bit line BL1 of the plane PLN1, the sense amplifier SA1 of the sense amplifier 1, the latch circuit group “latch0” of the latch circuit unit Latch0, a description thereof will be omitted.

### 1-6. Operation Example

### <1-6-1. Summary of Program Operation>

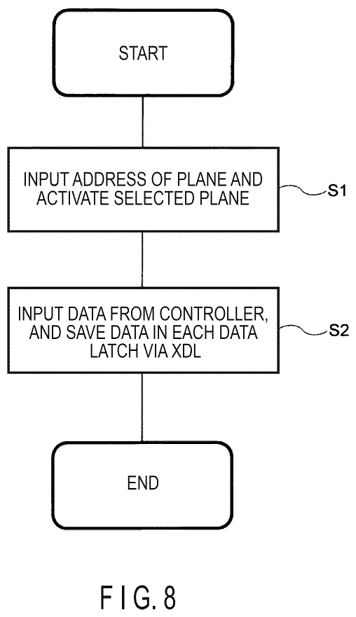

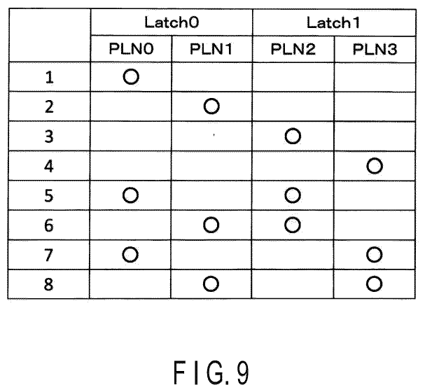

Using FIG. 8 and FIG. 9, a summary of a program operation of the non-volatile memory 2 according to the present embodiment will be described. FIG. 8 is a diagram illustrating a flowchart of the program operation of the non-volatile memory 2 according to the present embodiment. FIG. 9 is a diagram illustrating combinations of activated planes at the time of the program operation of the non-volatile memory 2 according to the present embodiment. A description of configurations that are the same as or similar to the configurations in FIG. 1 to FIG. 7 may be omitted.

In the present embodiment, since the two sense amplifier modules 70 are commonly connected to the same latch circuit unit 73 in the non-volatile memory 2, the two planes PLN sharing the latch circuit unit 73 cannot perform a TLC operation (i.e., programming data using each memory cell as TLC) independently from each other. For example, the sense amplifier 0 and the sense amplifier 1 that are connected to the latch circuit unit Latch0 cannot operate at the same time, and the sense amplifier 2 and the sense amplifier 3 that are connected to the Latch1 cannot operate at the same time. Only one of the two planes PLN sharing the latch circuit unit 73 is activated by the selection signal that is input into a corresponding one of the selectors 140. The other one of the selectors 140 of the two planes PLN sharing the latch circuit unit 73 is turned off.

The memory controller 1 generates a command set for causing the non-volatile memory 2 to execute the program operation in accordance with a program request from the host 4, and transmits the command set to the non-volatile memory 2. When the command set is received by the non-volatile memory 2, the operation illustrated in the flowchart of FIG. 8 is started.

In accordance with the command set, the input/output circuit 22 transmits, for example, received write data DAT to the latch circuit unit 73 of the corresponding plane PLN, and transmits received address information ADD and command CMD to the register 25. In accordance with an instruction from the sequencer 24, the register 25 transmits the column address in the address information ADD to the column decoder 30, transmits the row address in the address information ADD to the row decoder 29 of the corresponding plane PLN, and inputs a plane address (e.g., a selection signal) in the address information ADD to the selector 140 (or the sense amplifier module 70) connected to the corresponding plane PLN. Accordingly, the selected plane PLN is activated (S1).

Next, the write data DAT received from the memory controller 1 is input to the latch circuit unit 73 of the activated plane PLN, and is saved in the latch circuits SDL, ADL, BDL, and CDL via the latch circuit XDL (S2).

The command register receives the command CMD from the input/output circuit 22, and transmits the command CMD to the sequencer 24. The sequencer 24 executes the program operation in accordance with the command CMD held in the command register.

Here, the plane PLN0 and the plane PLN1 that share the latch circuit unit Latch0 are not selected at the same time. The plane PLN2 and the plane PLN3 that share the latch circuit unit Latch1 are not selected at the same time. Accordingly, the activated plane(s) PLN is (are) one plane PLN or two planes PLN among the four planes PLN, and the combinations thereof are eight ways illustrated in FIG. 9 (O is the activated plane in FIG. 9).

### <1-6-2. Overview of Read Operation>

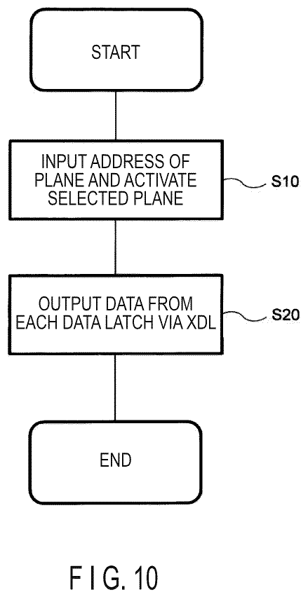

Using FIG. 10, an overview of a read operation of the non-volatile memory 2 according to the present embodiment will be described. FIG. 10 is a diagram illustrating a flowchart of a read operation of the non-volatile memory 2 according to the present embodiment. A description of configurations that are the same as or similar to the configurations in FIG. 1 to FIG. 9 may be omitted.

The memory controller 1 generates a command set for causing the non-volatile memory 2 to execute a read operation in accordance with a read request from the host 4, and transmits the command set to the non-volatile memory 2. When the command set is received by the input/output circuit 22 of the non-volatile memory 2, the operation illustrated in the flowchart of FIG. 10 is started.

In accordance with the command set, the input/output circuit 22 transmits, for example, the received address information ADD and command CMD to the register 25. In accordance with an instruction from the sequencer 24, the register 25 transmits the column address in the address information ADD to the column decoder 30, transmits the row address in the address information ADD to the row decoder 29 of the corresponding plane PLN, and inputs the plane address (selection signal) in the address information ADD to the selector 140 (or the sense amplifier module 70) connected to the corresponding plane PLN. Accordingly, the selected plane PLN is activated (S10).

The command register receives the command CMD from the input/output circuit 22, and transmits the command CMD to the sequencer 24. The sequencer 24 executes a read operation in accordance with the command CMD held in the command register.

Next, the read data DAT read from the memory cell array 21 of the activated plane PLN is output from the latch circuits SDL, ADL, BDL, and CDL via the latch circuit XDL (S20).

Next, the input/output circuit 22 receives status information STS from the register 25, and receives the read data DAT from the latch circuit XDL of the corresponding plane PLN. The input/output circuit 22 transmits the received status information STS and read data DAT to the memory I/F 18 included in the memory controller 1.

Here, the plane PLN0 and the plane PLN1 that share the latch circuit unit Latch0 are not selected at the same time. The plane PLN2 and the plane PLN3 that share the latch circuit unit Latch1 are not selected at the same time. Accordingly, the activated plane(s) PLN is (are) one plane PLN or two planes PLN among the four planes PLN, and the combinations thereof are eight ways illustrated in FIG. 9 as in the program operation.

### Second Embodiment

In the non-volatile memory 2 according to a second embodiment, the configuration of the latch circuit unit is different from that of the non-volatile memory 2 according to the first embodiment. Although details will be described later, in the present embodiment, all the four planes PLN can be activated by performing an SLC operation. A description of configurations that are the same as or similar to the configurations in the first embodiment may be omitted.

### 2-1. Configurations of Sense Amplifier SA and Latch Circuit

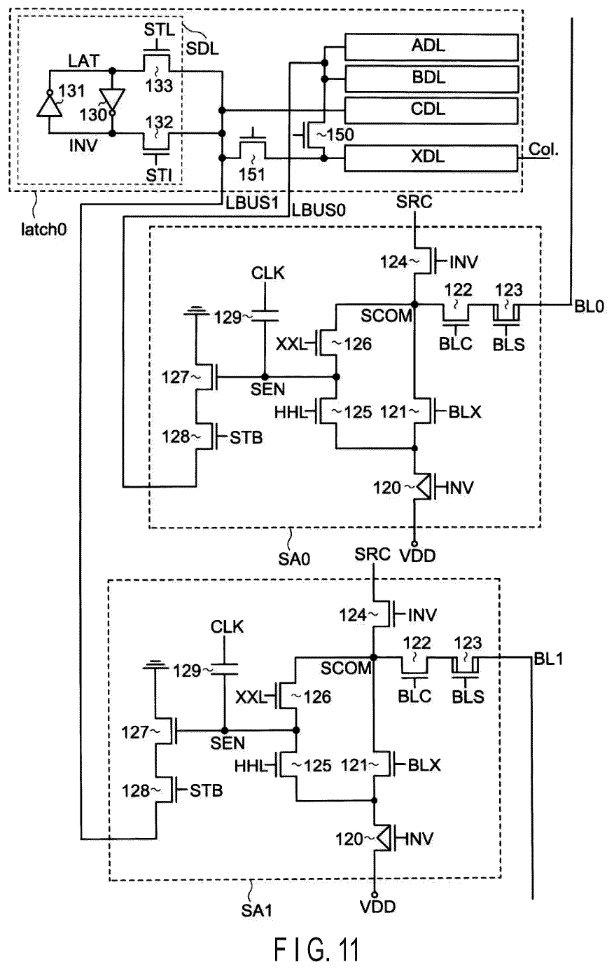

An example of the configurations of the sense amplifier SA and the latch circuit according to the present embodiment will be described. FIG. 11 is a circuit diagram illustrating an example of the configuration of the sense amplifier SA and the latch circuit according to the second embodiment. It is noted the configurations illustrated in FIG. 11 are examples, and do not limit the configurations of the sense amplifier SA and the latch circuit of the non-volatile memory according to the second embodiment. A description of configurations that are the same as or similar to the configurations in the first embodiment may be omitted.

FIG. 11 illustrates the circuit configurations of the sense amplifiers SA of the two different sense amplifier modules 70 connected to the bit lines BL of the two different planes PLN. For example, the bit line BL0 of the plane PLN0 is connected to the sense amplifier SA0 of the sense amplifier 0, and the bit line BL1 of the plane PLN1 is connected to the sense amplifier SA1 of the sense amplifier 1. Since the circuit configuration of the sense amplifier SA is the same as that in the first embodiment, a description thereof will be omitted.

The latch circuit unit 73 includes a plurality of latch circuit groups. Each of the latch circuit groups includes the latch circuits SDL, ADL, BDL, CDL, and XDL. The sense amplifier SA0 is electrically connected to the latch circuits ADL, BDL, and XDL of the latch circuit group “latch0” via a bus LBUS0. The sense amplifier SA1 is electrically connected to the latch circuits SDL, CDL, and XDL of the latch circuit group “latch0” via a bus LBUS1. In the present embodiment, there is no selector 140, and the other ends of the transistors 128 are directly connected to the bus LBUS0 or the bus LBUS1, respectively.

The latch circuits SDL, ADL, BDL, and CDL temporarily store read data or write data. For example, in the case of a read operation of the plane PLN0, read data is stored in one of the latch circuits ADL and BDL via the bus LBUS0. In the case of a write operation of the plane PLN0, write data of the latch circuit XDL is stored in one of the latch circuits ADL and BDL via a switch 150. In addition, for example, in the case of a read operation of the plane PLN1, read data is stored in one of the latch circuits SDL and CDL via the bus LBUS1. In the case of a write operation of the plane PLN1, write data of the latch circuit XDL is stored in one of the latch circuits SDL and CDL via a switch 151.

The latch circuit XDL is commonly connected to the bus LBUS0 and the bus LBUS1. The latch circuit XDL is connected to the bus LBUS0 via the switch 150. The latch circuit XDL is connected to the bus LBUS1 via the switch 151. The switch 150 connects the latch circuit XDL and the sense amplifier SA0. The switch 151 connects the latch circuit XDL and the sense amplifier SA1. One end of the switch 150 is connected to the latch circuit XDL, and the other end of the switch 150 is connected to the bus LBUS0. One end of the switch 151 is connected to the latch circuit XDL, and the other end of the switch 151 is connected to the bus LBUS1. A signal DSW150 for turning on or off the switch 150 is input to a gate of the switch 150, and a signal DSW151 for turning on or off the switch 151 is input to a gate of the switch 151. The signal DSW150 and the signal DSW151 that are input to the switch 150 and the switch 151, respectively, are generated by, for example, the sequencer 24. For example, when the switch 150 is in an on state, the sense amplifier SA0 and the latch circuit XDL are electrically connected, and when the switch 151 is in an on state, the sense amplifier SA1 and the latch circuit XDL are electrically connected. Either one of the switch 150 and the switch 151 of the two buses LBUS sharing the latch circuit XDL is turned off.

Since the circuit configurations of the bit line BL of the plane PLN2, the sense amplifier SA of the sense amplifier 2, the bit line BL of the plane PLN3, the sense amplifier SA of the sense amplifier 3, the latch circuit group of the latch circuit unit Latch1 are the same as the circuit configurations of the bit line BL0 of the plane PLN0, the sense amplifier SA of the sense amplifier 0, the bit line BL1 of the plane PLN1, the sense amplifier SA1 of the sense amplifier 1, the latch circuit group “latch0” of the latch circuit unit Latch0, a description thereof will be omitted.

Since the configuration of the memory system 3 according to the present embodiment is the same as the configuration of the memory system 3 according to the first embodiment except for the above-described configuration, a description thereof will be omitted.

### 2-2. Operation Example

### <2-2-1. Overview of Program Operation>

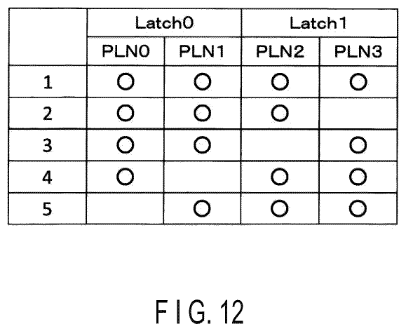

Using FIG. 8, FIG. 9, and FIG. 12, an overview of the program operation of the non-volatile memory 2 according to the present embodiment will be described. FIG. 12 is a diagram illustrating combinations of activated planes at the time of the program operation of the non-volatile memory 2 according to the present embodiment. A description of configurations that are the same as or similar to the configurations in the first embodiment may be omitted.

In the present embodiment, since the non-volatile memory 2 performs an SLC operation by dividing each latch circuit group into two, even if the two sense amplifier modules 70 are connected to the common latch circuit unit 73, the two planes PLN sharing the latch circuit unit 73 can perform the SLC operation independently from each other. For example, the sense amplifier 0 and the sense amplifier 1 that are connected to the latch circuit unit Latch0 can operate at the same time, and the sense amplifier 2 and the sense amplifier 3 that are connected to the Latch1 can operate at the same time. Both of the two planes PLN sharing the latch circuit unit 73 may be activated.

On the other hand, in the present embodiment, the two sense amplifier modules 70 are connected to the common latch circuit XDL in the non-volatile memory 2. The two sense amplifier modules 70 are not connected to the latch circuit XDL at the same time. For example, when the sense amplifier SA0 and the latch circuit XDL are electrically connected, the sense amplifier SA1 and the latch circuit XDL are not electrically connected. When the sense amplifier SA1 and the latch circuit XDL are electrically connected, the sense amplifier SA0 and the latch circuit XDL are not electrically connected. That is, when the switch 150 is in an on state, the switch 151 is in an off state, and when the switch 151 is in the on state, the switch 150 is in the off state.

As illustrated in FIG. 8, the input/output circuit 22 transmits, for example, the received write data DAT to the latch circuit unit 73 of the corresponding plane PLN, and transmits the received address information ADD and command CMD to the register 25. In accordance with an instruction from the sequencer 24, the register 25 transmits the column address in the address information ADD to the column decoder 30, transmits the row address in the address information ADD to the row decoder 29 of the corresponding plane PLN, and inputs the plane address (selection signal) in the address information ADD to the sense amplifier module 70 connected to the corresponding plane PLN. Accordingly, the selected plane PLN selected is activated (S1).

Next, the write data DAT received from the memory controller 1 is input to the latch circuit unit 73 of the activated plane PLN, and is saved in the latch circuits SDL, ADL, BDL, and CDL via the latch circuit XDL (S2).

The command register receives the command CMD from the input/output circuit 22, and transmits the command CMD to the sequencer 24. The sequencer 24 executes the program operation in accordance with the command CMD held in the command register.

Here, the plane PLN0 and the plane PLN1 that share the latch circuit unit Latch0 may be selected at the same time. The plane PLN2 and the plane PLN3 that share the latch circuit unit Latch1 may be selected at the same time. Accordingly, the activated planes PLN are four planes PLN or three planes PLN among the four planes PLN, and the combinations thereof are five ways illustrated in FIG. 12 in addition to the eight ways in FIG. 9.

### <2-2-2. Overview of Read Operation>

Using FIG. 10, the overview of a read operation of the non-volatile memory 2 according to the present embodiment will be described. A description of configurations that are the same as or similar to the configurations in the first embodiment may be omitted.

As illustrated in FIG. 10, the input/output circuit 22 transmits, for example, received address information ADD and command CMD to the register 25. In accordance with an instruction from the sequencer 24, the register 25 transmits the column address in the address information ADD to the column decoder 30, transmits the row address in the address information ADD to the row decoder 29 of the corresponding plane PLN, and inputs the plane address (selection signal) in the address information ADD to the sense amplifier module 70 connected to the corresponding plane PLN. Accordingly, the selected plane PLN is activated (S10). The command register receives the command CMD from the input/output circuit 22, and transmits the command CMD to the sequencer 24. The sequencer 24 executes a read operation in accordance with the command CMD held in the command register.

Next, the read data DAT read from the memory cell array 21 of the activated plane PLN is output from the latch circuits SDL, ADL, BDL, and CDL via the latch circuit XDL (S20).

Next, the input/output circuit 22 receives status information STS from the register 25, and receives the read data DAT from the latch circuit XDL of the corresponding plane PLN. The input/output circuit 22 transmits the received status information STS and read data DAT to the memory I/F 18 included in the memory controller 1.

Here, the plane PLN0 and the plane PLN1 that share the latch circuit unit Latch0 may be selected at the same time. The plane PLN2 and the plane PLN3 that share the latch circuit unit Latch1 may be selected at the same time. The planes PLN0 to PLN3 can operate independently from each other. Accordingly, the activated planes PLN are four planes PLN or three planes PLN among the four planes PLN, and the combinations thereof are five ways illustrated in FIG. 12 in addition to the eight ways in FIG. 9.

### Third Embodiment

In the non-volatile memory 2 according to a third embodiment, the configuration of the latch circuit group is different from that of the non-volatile memory 2 according to the first embodiment. A description of configurations that are the same as or similar to the configurations in the first embodiment may be omitted.

### <3-1. Configuration of Sense Amplifier SA and Latch Circuit>

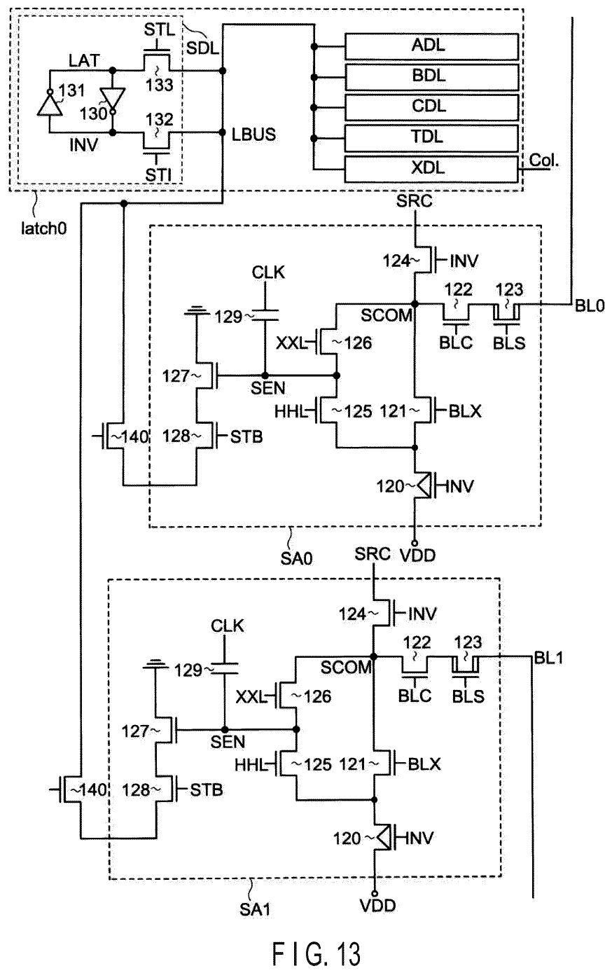

An example of the configurations of the sense amplifier SA and the latch circuit according to the present embodiment will be described. FIG. 13 is a circuit diagram illustrating an example of the configurations of the sense amplifier SA and the latch circuit according to the third embodiment. It is noted the configurations illustrated in FIG. 13 are examples, and do not limit the configurations of the sense amplifier SA and the latch circuit of the non-volatile memory according to the third embodiment. A description of configurations that are the same as or similar to the configurations in the first embodiment may be omitted.

FIG. 13 illustrates the circuit configurations of the sense amplifiers SA of two different sense amplifier modules 70 connected to the bit lines BL of two different planes PLN. For example, the bit line BL0 of the plane PLN0 is connected to the sense amplifier SA0 of the sense amplifier 0, and the bit line BL1 of the plane PLN1 is connected to the sense amplifier SA1 of the sense amplifier 1. Since the circuit configuration of the sense amplifier SA is similar to that in the first embodiment, a description thereof will be omitted.

The latch circuit unit 73 includes a plurality of latch circuit groups. The latch circuit group includes the latch circuits SDL, ADL, BDL, CDL, TDL, and XDL. The sense amplifier SA0 and the sense amplifier SAL are each electrically connected to the latch circuit group “latch0” of the latch circuit unit Latch0 via the bus LBUS. The two sense amplifiers SA0 and SAL are connected to the latch circuit group “latch 0” via the respective selectors 140.

The latch circuits SDL, ADL, BDL, TDL, and CDL temporarily store read data or write data. For example, in the case of a read operation, read data is stored in one of the latch circuits SDL, ADL, BDL, TDL, and CDL. In addition, for example, in the case of a write operation, write data of the latch circuit XDL is stored in one of the latch circuits SDL, ADL, BDL, TDL, and CDL. In the present embodiment, the non-volatile memory 2 includes a QLC (4 bit/Cell) memory cell transistor MT, and the number of latch circuits included in the latch circuit group is six.

The latch circuit XDL is used as a cache memory for input and output of data between the sense amplifier SA and the input/output circuit 22. More specifically, write data received from the memory controller 1 is transmitted to the latch circuits SDL, ADL, BDL, TDL, and CDL, or to the sense amplifier SA via the latch circuit XDL. In addition, read data stored in the latch circuits SDL, ADL, BDL, TDL, and CDL, or in the sense amplifier SA is transmitted to the memory controller 1 via the latch circuit XDL.

Since the circuit configurations of the bit line BL of the plane PLN2, the sense amplifier SA of the sense amplifier 2, the bit line BL of the plane PLN3, the sense amplifier SA of the sense amplifier 3, and the latch circuit group of the latch circuit unit Latch1 are similar to the circuit configurations of the bit line BL0 of the plane PLN0, the sense amplifier SA0 of the sense amplifier 0, the bit line BL1 of the plane PLN1, the sense amplifier SA1 of the sense amplifier 1, and the latch circuit group “latch0” of the latch circuit unit Latch 0, a description thereof will be omitted.

Since the configuration of the memory system 3 according to the present embodiment is similar to the configuration of the memory system 3 according to the first embodiment except for the above-described configuration, a description thereof will be omitted.

### 3-2. Operation Example

In the present embodiment, since the two sense amplifier modules 70 are connected to the common latch circuit unit 73 in the non-volatile memory 2, the two planes PLN sharing the latch circuit unit 73 cannot perform a QLC operation independently from each other. For example, the sense amplifier 0 and the sense amplifier 1 that are connected to the Latch 0 cannot operate at the same time, and the sense amplifier 2 and the sense amplifier 3 that are connected to the Latch1 cannot operate at the same time. Either one of the two planes PLN sharing the latch circuit unit 73 is activated by the selection signal that is input into the selector 140. Either one of the selectors 140 of the two planes PLN sharing the latch circuit unit 73 is turned off. Since the program operation and the read operation of the non-volatile memory 2 according to the present embodiment are similar to the program operation and the read operation of the non-volatile memory 2 according to the first embodiment, a description thereof will be omitted.

### Fourth Embodiment

In the non-volatile memory 2 according to a fourth embodiment, the configuration of the latch circuit group is different from that of the non-volatile memory 2 according to the second embodiment. A description of configurations that are the same as or similar to the configurations in the second embodiment may be omitted.

### 4-1. Configuration of Sense Amplifier SA and Latch Circuit

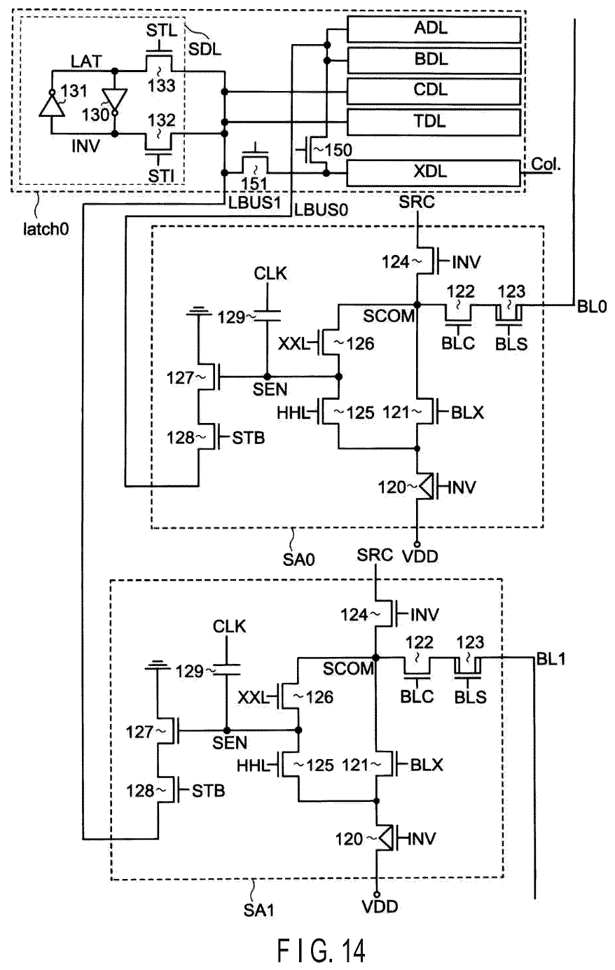

An example of the configurations of the sense amplifier SA and the latch circuit according to the present embodiment will be described. FIG. 14 is a circuit diagram illustrating an example of the configurations of the sense amplifier SA and the latch circuit according to the fourth embodiment. It is noted the configurations illustrated in FIG. 14 are examples, and do not limit the configurations of the sense amplifier SA and the latch circuit of the non-volatile memory according to the fourth embodiment. A description of configurations that are the same as or similar to the configurations in the second embodiment may be omitted.

FIG. 14 illustrates the circuit configurations of the sense amplifiers SA of two different sense amplifier modules 70 connected to the bit lines BL of two different planes PLN. For example, the bit line BL0 of the plane PLN0 is connected to the sense amplifier SA0 of the sense amplifier 0, and the bit line BL1 of the plane PLN1 is connected to the sense amplifier SA1 of the sense amplifier 1. Since the circuit configuration of the sense amplifier SA is similar to that in the first embodiment, a description thereof will be omitted.

The latch circuit unit 73 includes a plurality of latch circuit groups. The latch circuit group includes the latch circuits SDL, ADL, BDL, CDL, TDL, and XDL. The sense amplifier SA0 is electrically connected to the latch circuits ADL, BDL, and XDL of the latch circuit group “latch0” via the bus LBUS0. The sense amplifier SA1 is electrically connected to the latch circuits SDL, CDL, TDL, and XDL of the latch circuit group “latch0” via the bus LBUS1. In the present embodiment, there is no selector 140, and the other ends of the transistors 128 are directly connected to the bus LBUS0 or the bus LBUS1, respectively.

The latch circuits SDL, ADL, BDL, TDL, and CDL temporarily store read data or write data. For example, in the case of a read operation of the plane PLN0, read data is stored in one of the latch circuits ADL and BDL via the bus LBUS0. In the case of a write operation of the plane PLN0, write data of the latch circuit XDL is stored in one of the latch circuits ADL and BDL via the switch 150. In addition, for example, in the case of a read operation of the plane PLN1, read data is stored in one of the latch circuits SDL, TDL, and CDL via the bus LBUS1. In the case of a write operation of the plane PLN1, write data of the latch circuit XDL is stored in one of the latch circuits SDL, TDL, and CDL via the switch 151. In the present embodiment, the non-volatile memory 2 includes a QLC (4 bit/Cell) memory cell transistor MT, and the number of latch circuits included in the latch circuit group is six.

The latch circuit XDL is commonly connected to the bus LBUS0 and the bus LBUS1. The latch circuit XDL is connected to the bus LBUS0 via the switch 150. The latch circuit XDL is connected to the bus LBUS1 via the switch 151. The switch 150 connects the latch circuit XDL and the sense amplifier SA0. The switch 151 connects the latch circuit XDL and the sense amplifier SA1. The one end of the switch 150 is connected to the latch circuit XDL, and the other end of the switch 150 is connected to the bus LBUS0. The one end of the switch 151 is connected to the latch circuit XDL, and the other end of the switch 151 is connected to the bus LBUS1. The signal DSW150 for turning on or off the switch 150 is input to the gate of the switch 150, and the signal DSW151 for turning on or off the switch 151 is input to the gate of the switch 151. The signal DSW150 and the signal DSW151 that are input to the switch 150 and the switch 151, respectively, are generated by, for example, the sequencer 24. For example, when the switch 150 is in the on state, the sense amplifier SA0 and the latch circuit XDL are electrically connected, and when the switch 151 is in the on state, the sense amplifier SA1 and the latch circuit XDL are electrically connected. Either one of the switch 150 and the switch 151 of the two buses LBUS sharing the latch circuit XDL is turned off.

The circuit configurations of the bit line BL of the plane PLN2, the sense amplifier SA of the sense amplifier 2, the bit line BL of the plane PLN3, the sense amplifier SA of the sense amplifier 3, the latch circuit group of the latch circuit unit Latch1 are similar to the circuit configurations of the bit line BL0 of the plane PLN0, the sense amplifier SA0 of the sense amplifier 0, the bit line BL1 of the plane PLN1, the sense amplifier SA1 of the sense amplifier 1, the latch circuit group “latch0” of the latch circuit unit Latch0, a description thereof will be omitted.

Since the configuration of the memory system 3 according to the present embodiment is the same as the configuration of the memory system 3 according to the first embodiment except for the above-described configuration, a description thereof will be omitted.

### 4-2. Operation Example

In the present embodiment, since the non-volatile memory 2 performs an SLC operation by dividing each latch circuit group into two, even if the two sense amplifier modules 70 are connected to the common latch circuit unit 73, the two planes PLN sharing the latch circuit unit 73 can perform the SLC operation independently from each other. For example, the sense amplifier 0 and the sense amplifier 1 that are connected to the Latch 0 can operate at the same time, and the sense amplifier 2 and the sense amplifier 3 that are connected to the Latch1 can operate at the same time. Both the two planes PLN sharing the latch circuit unit 73 are activated.

On the other hand, in the present embodiment, the two sense amplifier modules 70 are connected to the common latch circuit XDL in the non-volatile memory 2. The two sense amplifier modules 70 are not connected to the latch circuit XDL at the same time. For example, when the sense amplifier SA0 and the latch circuit XDL are electrically connected, the sense amplifier SA1 and the latch circuit XDL are not electrically connected. When the sense amplifier SA1 and the latch circuit XDL are electrically connected, the sense amplifier SA0 and the latch circuit XDL are not electrically connected. That is, when the switch 150 is in the on state, the switch 151 is in the off state, and when the switch 151 is in the on state, the switch 150 is in the off state. Since the program operation and the read operation of the non-volatile memory 2 according to the present embodiment are similar to the program operation and the read operation of the non-volatile memory 2 according to the second embodiment, a description thereof will be omitted.

### Fifth Embodiment

The non-volatile memory 2 according to a fifth embodiment differs in the number of planes PLN from the non-volatile memories 2 according to the first embodiment to the fourth embodiment. A description of configurations that are the same as or similar to the configurations in the first embodiment to the fourth embodiment may be omitted.

### <5-1. Configuration of Non-Volatile Memory 2>

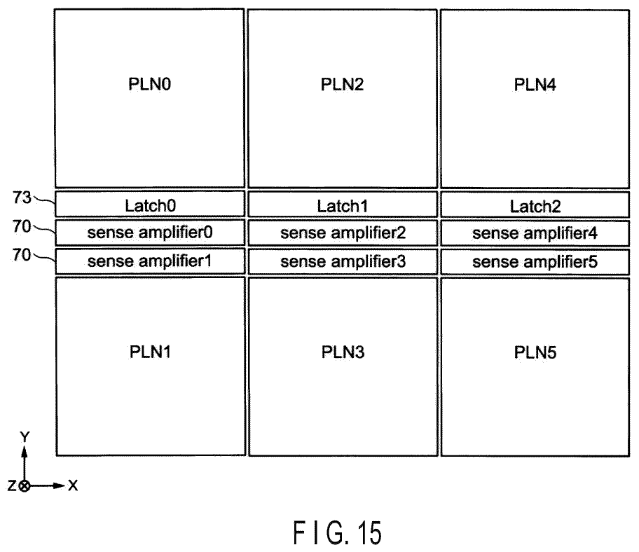

As illustrated in FIG. 15, the non-volatile memory 2 includes a plurality of planes PLN (PLN0, PLN1, PLN2, PLN3, PLN4, PLN5). The plane PLN is a unit for performing write operations and read operations of data. In the present embodiment, the non-volatile memory 2 includes six planes PLN0, PLN1, PLN2, PLN3, PLN4, and PLN5.

Each memory cell array 21 is connected to, for example, the corresponding sense amplifier module 70, the corresponding row decoder 29, and the driver set 28. For example, the memory cell array 21 of the plane PLN0 is connected to the sense amplifier 0, the memory cell array 21 of the plane PLN1 is connected to the sense amplifier 1, the memory cell array 21 of the plane PLN2 is connected to the sense amplifier 2, the memory cell array 21 of the plane PLN3 is connected to the sense amplifier 3, the memory cell array 21 of the plane PLN4 is connected to the sense amplifier 4, and the memory cell array 21 of the plane PLN5 is connected to the sense amplifier 5. The memory cell array 21 of the plane PLN0 is connected to the row decoder 29 of the plane PLN0, the memory cell array 21 of the plane PLN1 is connected to the row decoder 29 of the plane PLN1, the memory cell array 21 of the plane PLN2 is connected to the row decoder 29 of the plane PLN2, the memory cell array 21 of the plane PLN3 is connected to the row decoder 29 of the plane PLN3, the memory cell array 21 of the plane PLN4 is connected to the row decoder 29 of the plane PLN4, and the memory cell array 21 of the plane PLN5 is connected to the row decoder 29 of the plane PLN5.

Further, the plurality of sense amplifier modules 70 are connected to the common latch circuit unit 73. For example, the sense amplifier 0 and the sense amplifier 1 are connected to the Latch 0, the sense amplifier 2 and the sense amplifier 3 are connected to the Latch1, and the sense amplifier 4 and the sense amplifier 5 are connected to a Latch 2. In the present embodiment, since the two sense amplifier modules 70 are connected to the common latch circuit unit 73, the size of peripheral circuits can be reduced by one latch circuit unit 73. Therefore, the chip size of the non-volatile memory 2 can be reduced, and the manufacturing cost can be reduced by increasing the number of chips that can be obtained per wafer.

As illustrated in FIG. 15, in the plan view, the two sense amplifier modules 70 connected to the common latch circuit unit 73 and this latch circuit unit 73 are arranged between the corresponding planes PLN. For example, the sense amplifier 0, the sense amplifier 1, and the Latch 0 are arranged between the plane PLN0 and the plane PLN1, the sense amplifier 2, the sense amplifier 3, and the latch circuit unit Latch1 are arranged between the plane PLN2 and the plane PLN3, and the sense amplifier 4, the sense amplifier 5, and the Latch 2 are arranged between the plane PLN4 and the plane PLN5. In the present embodiment, since the two sense amplifier modules 70 and the latch circuit unit 73 are arranged between the two planes PLN to which they are to be connected, connection can be efficiently made.

In FIG. 15, the latch circuit unit 73 is arranged adjacent to the plane PLN to which the latch circuit unit 73 is connected. For example, the plane PLN0, the Latch 0, the sense amplifier 0, the sense amplifier 1, and the plane PLN1 are arranged in this order, the plane PLN2, the latch circuit unit Latch1, the sense amplifier 2, the sense amplifier 3, and the plane PLN3 are arranged in this order, the plane PLN4, the Latch 2, the sense amplifier 4, the sense amplifier 5, and the plane PLN5 are arranged in this order. However, the latch circuit unit 73 is not be limited to this, and the latch circuit unit 73 may be arranged between the two sense amplifier modules 70.

Since the configurations of the six planes PLN, the six sense amplifier modules 70, and the three latch circuit units 73 according to the present embodiment can be directly applied to the memory systems 3 according to the first embodiment to the fourth embodiment, a description thereof will be omitted.

What is claimed is:

1. A semiconductor memory device, comprising:
a first plane of memory cell array including a first memory cell string and a first bit line connected to the first memory cell string;
a second plane of memory cell array including a second memory cell string and a second bit line connected to the second memory cell string;
a first sense amplifier connected to the first bit line, and configured to perform sensing of first read data that are read from a memory cell in the first memory cell string via the first bit line and apply voltages corresponding to first write data that are to be written to a memory cell in the first memory cell string, to the first bit line;
a second sense amplifier connected to the second bit line, and configured to perform sensing of second read data that are read from a memory cell in the second memory cell string and apply voltages corresponding to second write data that are to be written to a memory cell in the second memory cell string, to the second bit line; and
a latch circuit array connected to the first sense amplifier and the second sense amplifier and configured to store the first read data, the first write data, the second read data, and the second write data.

2. The semiconductor memory device of claim 1, wherein the first sense amplifier, the second sense amplifier, and the latch circuit array are arranged between the first plane of memory cell array and the second plane of memory cell array in a first direction.

3. The semiconductor memory device of claim 2, wherein the latch circuit array is arranged between the first plane of memory cell array and the first sense amplifier in the first direction.

4. The semiconductor memory device of claim 1, further comprising:
a first switch connected between the latch circuit array and the first sense amplifier; and
a second switch connected between the latch circuit array and the second sense amplifier.

5. The semiconductor memory device of claim 4, further comprising:
a control circuit configured to turn on the first switch and turn off the second switch in response to receiving first address information indicating a location in the first plane of memory cell array.

6. The semiconductor memory device of claim 5, wherein the control circuit is further configured to turn off the first switch and turn on the second switch in response to receiving second address information indicating a location in the second plane of memory cell array.

7. The semiconductor memory device of claim 5, wherein
the latch circuit array includes a plurality of first latch circuits, and a second latch circuit connected to an input/output circuit, and
the plurality of first latch circuits is configured to receive the first write data and the second write data from the input/output circuit via the second latch circuit, and output the first read data and the second read data to the input/output circuit via the second latch circuit.

8. The semiconductor memory device of claim 7, wherein
each of the first write data, the second write data, the first read data, and the second read data is multi-bit data, and
each of the first latch circuits stores one bit of the first write data, one bit of the second write data, one bit of the first read data, and one bit of the second read data.

9. The semiconductor memory device of claim 7, wherein a number of the first latch circuits is equal to or greater than a maximum number of bits of data storable in each memory cell in the first plane of memory cell array and a maximum number of bits of data storable in each memory cell in the second plane of memory cell array.

10. The semiconductor memory device of claim 7, wherein a number of the first latch circuits is four or more.

11. The semiconductor memory device of claim 1, wherein
the latch circuit array includes a first plurality of latch circuits, a second plurality of latch circuits, and a second latch circuit connected to an input/output circuit, and
the semiconductor memory device further comprises:
a first switch connected between the first plurality of latch circuits and the second latch circuit; and
a second switch connected between the second plurality of latch circuits and the second latch circuit.

12. The semiconductor memory device of claim 11, further comprising:
a control circuit configured to turn on the first switch and turn off the second switch in response to receiving first address information indicating a location in the first plane of memory cell array.

13. The semiconductor memory device of claim 12, wherein the control circuit is further configured to turn off the first switch and turn on the second switch in response to receiving second address information indicating a location in the second plane of memory cell array.

14. The semiconductor memory device of claim 11, wherein
the first plurality of latch circuits is configured to receive the first write data from the input/output circuit via the second latch circuit, and output the first read data to the input/output circuit via the second latch circuit, and
the second plurality of latch circuits is configured to receive the second write data from the input/output circuit via the second latch circuit, and output the second read data to the input/output circuit via the second latch circuit.

15. The semiconductor memory device of claim 14, wherein
each of the first write data, the second write data, the first read data, and the second read data is multi-bit data,
each of the first plurality of latch circuits stores one bit of the first write data and one bit of the first read data, and
each of the second plurality of latch circuits stores one bit of the second write data and one bit of the second read data.

16. The semiconductor memory device of claim 1, further comprising:
a third plane of memory cell array including a third memory cell string and a third bit line connected to the third memory cell string;
a fourth plane of memory cell array including a fourth memory cell string and a fourth bit line connected to the fourth memory cell string;
a third sense amplifier connected to the third bit line, and configured to perform sensing of third read data that are read from a memory cell in the third memory cell string and apply voltages corresponding to third write data that are to be written to a memory cell in the third memory cell string, to the third bit line;
a fourth sense amplifier connected to the fourth bit line, and configured to perform sensing of fourth read data that are read from a memory cell in the fourth memory cell string and apply voltages corresponding to fourth write data that are to be written to a memory cell in the fourth memory cell string, to the fourth bit line; and
a second latch circuit array connected to the third sense amplifier and the fourth sense amplifier and configured to store the third read data, the third write data, the fourth read data, and the fourth write data.

17. The semiconductor memory device of claim 16, wherein the third sense amplifier, the fourth sense amplifier, and the second latch circuit array are arranged between the third plane of memory cell array and the fourth plane of memory cell array.

18. The semiconductor memory device of claim 16, further comprising:
a fifth plane of memory cell array including a fifth memory cell string and a fifth bit line connected to the fifth memory cell string;
a sixth plane of memory cell array including a sixth memory cell string and a sixth bit line connected to the sixth memory cell string;
a fifth sense amplifier connected to the fifth bit line, and configured to perform sensing of fifth read data that are read from a memory cell in the fifth memory cell string and apply voltages corresponding to fifth write data that are to be written to a memory cell in the fifth memory cell string, to the fifth bit line;
a sixth sense amplifier connected to the sixth bit line, and configured to perform sensing of sixth read data that are read from a memory cell in the sixth memory cell string and apply voltages corresponding to sixth write data that are to be written to a memory cell in the sixth memory cell string, to the sixth bit line; and
a third latch circuit array connected to the fifth sense amplifier and the sixth sense amplifier and configured to store the fifth read data, the fifth write data, the sixth read data, and the sixth write data.

19. The semiconductor memory device of claim 18, wherein the fifth sense amplifier, the sixth sense amplifier, and the third latch circuit array are arranged between the fifth plane of memory cell array and the sixth plane of memory cell array.

20. The semiconductor memory device of claim 18, wherein
the first sense amplifier, the second sense amplifier, and the latch circuit array are arranged between the first plane of memory cell array and the second plane of memory cell array in a first direction,
the third sense amplifier, the fourth sense amplifier, and the second latch circuit array are arranged between the third plane of memory cell array and the fourth plane of memory cell array in the first direction,
the fifth sense amplifier, the sixth sense amplifier, and the third latch circuit array are arranged between the fifth plane of memory cell array and the sixth plane of memory cell array in the first direction,
the first, third, and fifth planes of memory cell array are arranged in a second direction, and
the second, fourth, and sixth planes of memory cell array are arranged in the second direction.
